(19) United States
(12) Patent Application Publication
(10) Pub. No.: US 2014/0285973 A1
(43) Pub. Date: Sep. 25, 2014

(54) HOUSING AND POWER MODULE HAVING THE SAME

(71) Applicant: SAMSUNG ELECTRO-MECHANICS CO., LTD., Suwon (KR)

(72) Inventors: Chang Seob HONG, Suwon (KR); Young Hoon Kwak, Suwon (KR); Kwang Soo Kim, Suwon (KR)

(21) Appl. No.: 13/905,902

(22) Filed: May 30, 2013

(30) Foreign Application Priority Data
Mar. 21, 2013 (KR) 10-2013-0030170

(51) Int. Cl. H05K 5/02; H05K 7/20

(52) U.S. Cl. CPC H05K 5/0221; H05K 7/20436
USPC 361/709

(57) ABSTRACT

There are provided housing, capable of preventing a fastening part from being damaged by stress generated at the time of assembly thereof, and a power module having the same. The housing for the power module includes a body part having a space formed therein, the space accommodating a module substrate on which electronic elements are mounted, a plurality fastening parts formed to be protruded from side surfaces of the body part, and an elastic member coupled to the fastening parts in a plate spring manner and elastically supporting lower portions of the fastening parts.

### CROSS-REFERENCE TO RELATED APPLICATIONS

This application claims the priority of Korean Patent Application No. 10-2013-0030170, filed on Mar. 21, 2013, in the Korean Intellectual Property Office, the disclosure of which is incorporated herein by reference.

### BACKGROUND OF THE INVENTION

1. Field of the Invention

The present invention relates to a housing and a power module having the same, and more particularly, to a housing capable of preventing a fastening part from being damaged due to stress generated at the time of assembly thereof and a power module having the same.

2. Description of the Related Art

In accordance with an increase in heat generated by power modules due to increases in energy usage and the occurrence of component miniaturization/integration, power modules tend to increase cooling efficiency.

Since heat generated by power modules may significantly influence the lifespan of parts due to thermal deformation of a structure, a great deal of research has been conducted into structures increasing cooling performance.

However, since a complex structure for increasing efficiency may lead to an increase in manufacturing costs at the time of a mass production, a high efficiency structure which is substantially simple and is easily manufactured is demanded.

In addition to this, since a heat transfer rate may be decreased due to warpage generated by the lamination of several materials having different coefficients of thermal expansion, thereby increasing thermal resistance whereby cooling performance may be deteriorated, a method capable of improving structural flatness in a substrate is demanded.

Meanwhile, a power module according to the related art is manufactured in a form in which a housing is coupled to a heat sink and a substrate having semiconductor elements mounted thereon is interposed between the housing and the heat sink in order to cool the power module.

In this configuration, a method in which the housing is fastened to the heat sink by directly inserting a screw into a hole formed in the housing has mainly been used.

However, the power module according to the related art may be defective in that stress may be intensively applied to a portion in which the screw is fastened in the housing by a screw fastening. In addition, this defect may lead to damage to the housing and degrade contact reliability between the substrate and the housing, thereby degrading efficiency of the power module.

### RELATED ART DOCUMENT

(Patent Document 1) Korean Patent Laid-Open Publication No. 1999-012187

### SUMMARY OF THE INVENTION

An aspect of the present invention provides a housing capable of minimizing a damage to a fastening part of the housing at the time of assembly thereof and a power module having the same.

According to an aspect of the present invention, there is provided a housing for a power module, including: a body part having a space formed therein, the space accommodating a module substrate on which electronic elements are mounted; a plurality fastening parts formed to be protruded from side surfaces of the body part; and an elastic member coupled to the fastening parts in a plate spring manner and elastically supporting lower portions of the fastening parts.

The elastic member may include: a support plate disposed on upper surfaces of the fastening parts; and elastic parts respectively extended from both ends of the support plate to be disposed below the fastening parts, elastically deformed when the body part is fastened to a heat radiation substrate, and supporting the fastening parts.

The elastic parts may be respectively formed to have an arc shape and may be disposed such that distal ends thereof are spaced apart from lower surfaces of the fastening parts.

The elastic parts may have lower ends thereof disposed in a position lower than that of a lower surface of the body part.

The fastening parts may be protruded such that lower surfaces thereof are disposed on a plane different from that of a lower surface of the body part.

Each of the fastening parts may include: a coupling part formed to have a flat plate shape and having a fixing screw coupled thereto; and supporting parts vertically extended from opposing side surfaces of the coupling part to supplement rigidity of the coupling part.

The coupling part may have a lower surface thereof disposed in a position higher than that of a lower surface of the body part in a vertical direction.

The body part may include one or more through-holes through which external connection terminals mounted on the module substrate are externally exposed.

According to another aspect of the present invention, there is provided a housing for a power module, including a plurality of fastening parts protruded from side surfaces of a body part; and an elastic member non-linearly and elastically deformed and elastically supporting lower portions of the fastening parts.

According to another aspect of the present invention, there is provided a power module, including: a heat radiation substrate; a module substrate disposed on the heat radiation substrate and having one electronic elements mounted thereon; and a housing accommodating the module substrate and coupled to the heat radiation substrate, wherein the housing includes: a plurality of fastening parts protruded from side surfaces of the housing and coupled to the heat radiation substrate by a fixing screw, and an elastic member coupled to the fastening parts in a plate spring manner and elastically supporting lower portions of the fastening parts.

The elastic member may include: a support plate disposed on upper surfaces of the fastening parts; and elastic parts respectively extended from both ends of the support plate to be disposed below the fastening parts, elastically deformed when the body part is fastened to the heat radiation substrate, and supporting the fastening parts.

The fastening part may be protruded such that lower surfaces thereof are disposed on a plane different from that of a lower surface of the body part, and the elastic parts of the elastic member may be interposed between the fastening parts and the heat radiation substrate to provide elastic force.

The elastic parts may have a first inflection point primarily deformed and a second inflection point additionally deformed according a degree of pressurization.

The elastic parts may be respectively formed to have an arc shape, the first inflection point may be deformed in such a manner that a curvature of the elastic parts is increased, and the second inflection point may be deformed in such a manner that the curvature of the elastic parts is decreased.

The elastic parts may be non-linearly and elastically deformed and may elastically support the lower portions of the fastening parts.

According to another aspect of the present invention, there is provided a power module, including: a heat radiation substrate; a module substrate disposed on the heat radiation substrate and having one or more electronic elements mounted thereon; and a housing accommodating the module substrate and coupled to the heat radiation substrate, wherein the housing includes: a plurality of fastening parts protruded from side surfaces of the housing and coupled to the heat radiation substrate by a fixing screw, and an elastic member non-linearly and elastically deformed and supporting lower portions of the fastening parts.

The elastic parts may have a first inflection point primarily deformed and a second inflection point additionally deformed according a degree of pressurization.

The elastic parts may be respectively formed to have an arc shape, the first inflection point may be deformed in such a manner that a curvature of the elastic parts is increased, and the second inflection point may be deformed in such a manner that the curvature of the elastic parts is decreased.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically illustrating a power module according to an embodiment of the present invention;

FIG. 2 is a perspective view illustrating a housing to which a module substrate is coupled of the power module depicted in FIG. 1 only;

FIG. 3 is an exploded perspective view of FIG. 2;

FIG. 4 is a plan view schematically illustrating the housing of FIG. 3;

FIG. 5 is a bottom perspective view schematically illustrating the housing of FIG. 4;

FIG. 6 is a side view taken in direction A of FIG. 4;

FIG. 7 is a side view taken in direction B of FIG. 1; and

FIGS. 8 and 9 are partially enlarged views of part C of FIG. 7.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

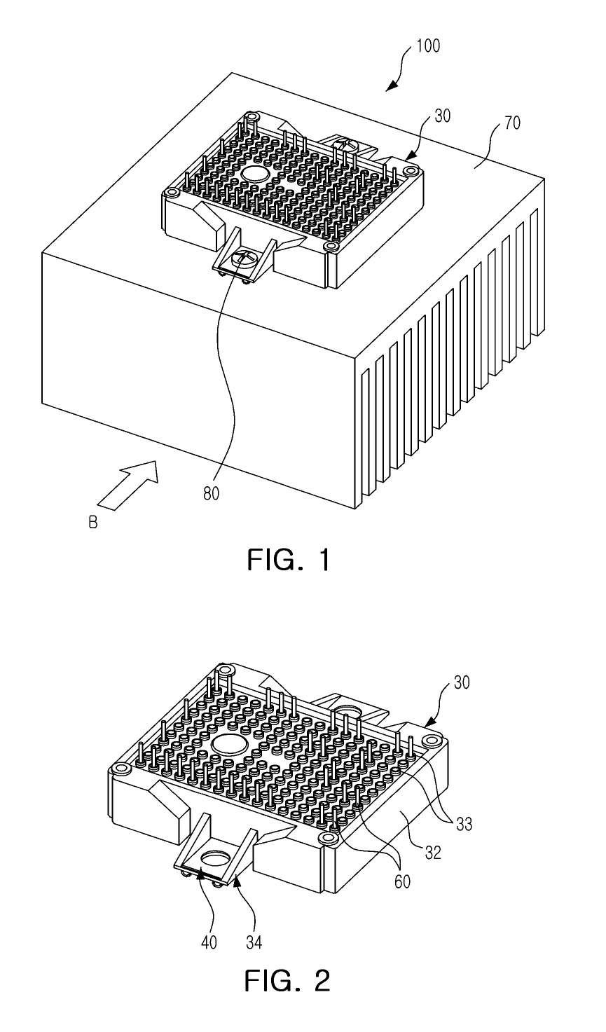

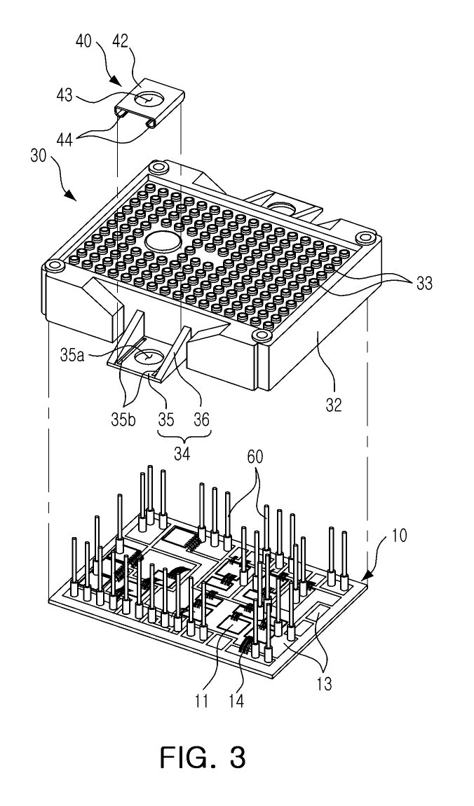

FIG. 1 is a perspective view schematically illustrating a power module according to an embodiment of the present invention, FIG. 2 is a perspective view illustrating a housing to which a module substrate is coupled of the power module depicted in FIG. 1 only, and FIG. 3 is an exploded perspective view of FIG. 2.

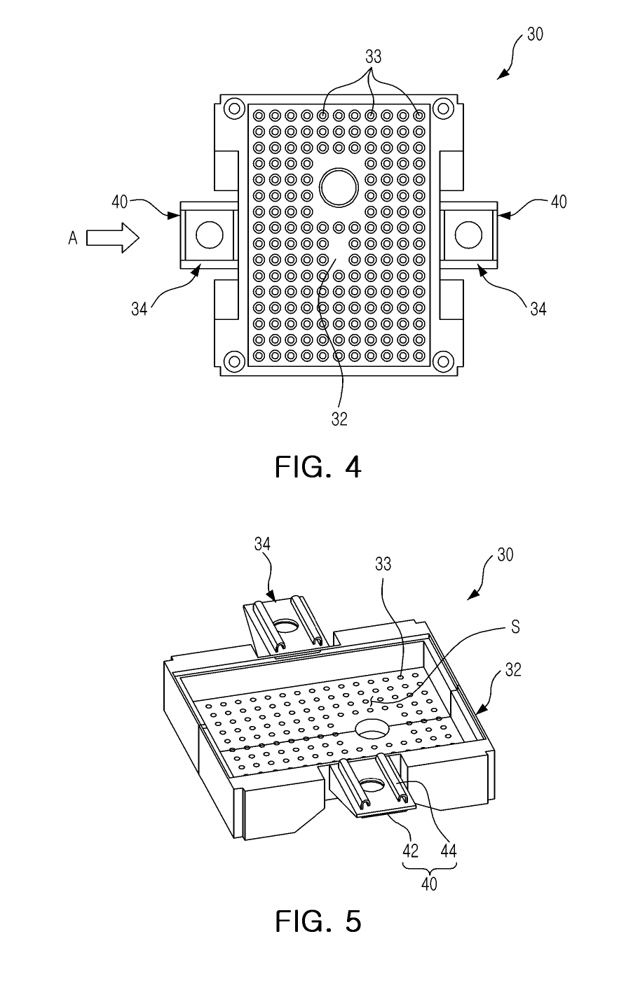

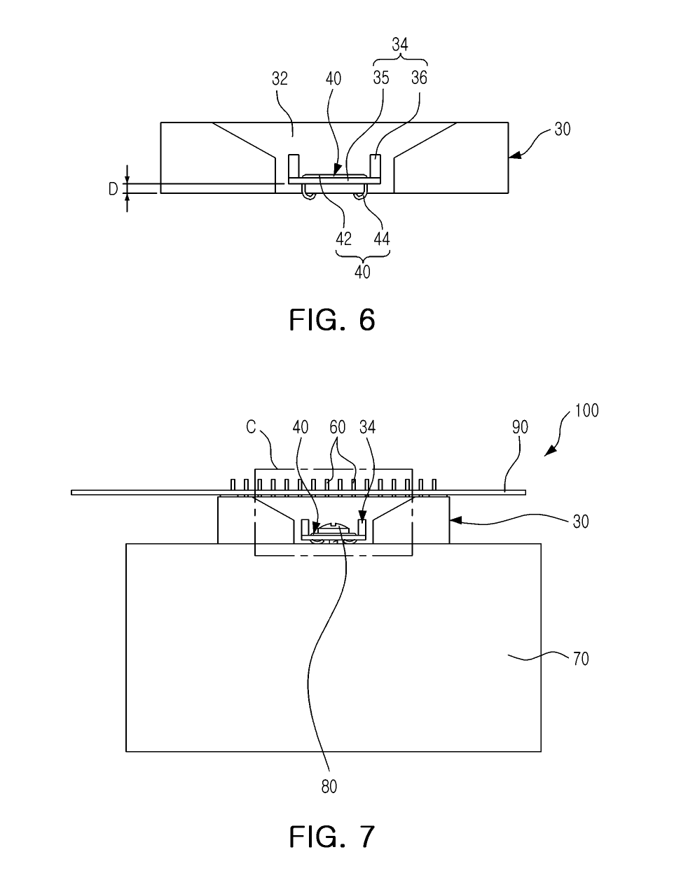

In addition, FIG. 4 is a plan view schematically illustrating the housing of FIG. 3, FIG. 5 is a bottom perspective view schematically illustrating the housing of FIG. 4, and FIG. 6 is a side view taken in direction A of FIG. 4.

Referring to FIGS. 1 through 6, a power module 100 according to an embodiment of the present invention may include a module substrate 10, one or more electronic elements 11, external connection terminals 60, a heat radiation substrate 70, and a housing 30.

The module substrate 10 may be a printed circuit board (PCB), a ceramic substrate, a pre-molded substrate, a direct bonded copper substrate (DBC), or an insulated metal substrate (IMS).

As depicted in FIG. 3, the module substrate 10 may be provided with amounting electrode (not depicted) for mounting the electronic elements 11 to be described below, a wiring pattern 13 for electrically connecting the electronic elements 11, and the like.

The wiring pattern 13 may be formed using a common layer forming methods, for example, a chemical vapor deposition (CVD) method and a physical vapor deposition (PVD) method, or may be formed through an electroplating process or an electroless plating process. In addition, the wiring pattern 13 may include a conductive material such as a metal. For example, the wiring pattern 13 may include aluminum, an aluminum alloy, copper, a copper alloy, or a combination of thereof.

In addition, the module substrate 10 may have one or more electronic elements 11 mounted on one surface thereof.

The electronic elements 11 according to the embodiment of the present invention may include a power element and a control element.

The power element may be a power converting element for controlling power or a power circuit element for controlling power such as a servo driver, an inverter, a power regulator, and a converter.

For example, the power element may include a power MOSFET, a bipolar junction transistor (BJT), an insulated-gate bipolar transistor (IGBT), a diode, or a combination thereof. That is, the power element according to the embodiment of the present invention may include all elements described above or a portion thereof.

Particularly, the power element according to the embodiment of the present invention may be configured of a plurality of pairs of insulated-gate bipolar transistors (IGBT) and the diodes, and this case, each pair is formed of an insulated-gate bipolar transistor (IGBT) and a diode. However, this is only an example, and the embodiment of the present invention is not necessarily limited thereto.

The control element may be connected to the power element through the wiring pattern 13, a bonding wire, or the like, such that it may control operations of the power element.

The control element may be a microprocessor, for example. However, in addition to this, a passive element such as a resistor, an inverter, or a condenser or an active element such as a transistor may further be added.

Meanwhile, a single control element or a plurality of control elements may be provided with respect to a single power element. That is, a type and amount of the control element may be appropriately selected according to a type and amount of the power element.

In the case in which the electronic elements 11 are electrically connected to the module substrate 10 through the bonding wire 14, the electronic elements 11 may be attached to one surface of the module substrate 10 through an adhesive member (not depicted). Here, the adhesive member may be conductive or non-conductive. For example, the adhesive member may be a conductive solder, a conductive paste, or a tape. In addition, as the adhesive member, a solder, a metal epoxy, a metal paste, a resin-based epoxy, or adhesive tape having excellent heat resistance may be used.

However, the present invention is not limited thereto and various methods may be used as needed. For example, the electronic elements 11 and the module substrate 10 may be electrically connected to each other using a flip chip bonding method, a solder ball, or the like.

The external connection terminals 60 may include a plurality of leads, and in this case, the respective leads are classified as an outer lead connected to an external substrate (90 of FIG. 7) and an inner lead fastened to the module substrate 10. That is, the outer lead refers to an externally exposed portion of the housing 30 and the inner lead refers to a portion located in the housing 30.

In the embodiment of the present invention, the external connection terminals 60 may be electrically connected to the electronic elements 11 through the wiring pattern 13, the bonding wire 14, or the like, formed on the module substrate 10.

The external connection terminals 60 described above may be formed of a material such as copper (Cu), aluminum (Al), or the like. However, the present invention is not limited thereto.

The housing 30 may form the entire exterior of the power module 100 and protect the electronic elements 11 and the module substrate 10 from external environments.

The housing 30 according to the embodiment of the present invention may include a body part 32 having an accommodating space formed therein, the accommodating space accommodating the module substrate 10 therein (denoted by “S” of FIG. 5), fastening parts 34 formed to be protruded outwardly from the body part 32, and an elastic member 40.

The body part 32 accommodates the module substrate 10 therein. Therefore, as depicted in FIG. 5, the body part 32 may have the accommodating space S formed therein, and the accommodating space S may have a size corresponding to a size of the module substrate 10 on which the electronic elements 11 are mounted.

Although the embodiment of the present invention illustrates a case in which the body part 32 is formed to have a hexahedral shape, the present invention is not limited thereto. For example, the body part 32 may be formed in various manners, and for example, may have a cylindrical shape, a poly-prismatic shape, or the like, as needed.

In addition, referring to FIG. 3, the body part 32 may have a plurality of through-holes 33 formed in one surface thereof, that is, an upper surface thereof. The through-holes 33 have the external connection terminals 60 inserted thereinto, the external connection terminals 60 being mounted on the module substrate 10, and the outer leads of the external connection terminals 60 may be externally exposed from the housing 30 through the through-holes 33.

The through-holes 33 may be positioned to correspond to locations of the external connection terminals 60, and the number of the through-holes 33 may be the same as that of the external connection terminals 60, but is not limited thereto. For example, as in the embodiment of the present invention, after forming the plurality of through-holes 33 in the upper surface of the body part 32, the through-holes 33 may be selectively used, as needed.

A plurality of the fastening parts 34 may be protruded from side surfaces of the body part 32. In the case of the embodiment of the present invention, the fastening parts 34 may be protruded outwardly from both sides of the body part 32 having a hexahedral shape. That is, the fastening parts 34 may be respectively formed on two side surfaces of the body part 32 disposed to be parallel to each other and may be protruded so as to correspond to each other.

Each of the fastening parts 34 may include a coupling part 35 protruded in a flat plate manner and supporting parts 36 vertically extended from opposing side surfaces of the coupling part 35 to reinforce rigidity of the coupling part 35.

The coupling part 35 may be provided with a screw hole 35a and fastening slits 35b. The screw hole 35a may have a fixing screw 80, a fixing member, inserted thereinto. In addition, the fastening slit 35b may have the elastic member 40 to be described below, inserted thereinto.

Particularly, the fastening part 34 according to the embodiment of the present invention may be protruded in a manner in which a lower surface thereof is disposed on a plane different from that of a lower surface of the body part 32. Specifically, the lower surface of the fastening part 34 may be disposed in a position higher than that of the lower surface of the body part 32 in a vertical direction.

Therefore, a space having a height equal to a spaced distance (D of FIG. 6) in the vertical direction may be formed between the lower surfaces of the fastening parts 34 and the lower surface of the body part 32.

In accordance with the formation of the above-mentioned space, in the case in which the fastening parts 34 are fastened to the heat radiation substrate 70 to be described below, the fastening parts 34 may be bent downwardly and deformed through the space so as to be fastened to the heat radiation substrate 70. Elastic force generated therefrom may act as force firmly adhering the heat radiation substrate 70 to the housing 30.

The elastic member 40 may be coupled to the fastening parts 34 to elastically support lower portions of the fastening parts 34.

As depicted in FIG. 3, the elastic member 40 may have a plate spring shape, and specifically, may be formed in a manner in which both ends of a metal plate material having a flat bar shape are bent. To this end, the elastic member 40 according to the embodiment of the present invention may include a support plate 42, which is a flat surface, disposed on one surface of the coupling part 35 and elastic parts 44 bent from both ends of the support plate 42.

The support plate 42 is disposed on the upper surface of the coupling part 35 so as to contact the fixing screw 80 when the fixing screw 80, the fixing member, is coupled to the coupling part 35. Therefore, the support plate 42 is also provided with a fastening hole 43 for inserting the fixing screw 80 thereinto and the fastening hole 43 may be formed to have the same size as the screw hole 35a of the coupling part 35.

The elastic parts 44 may be formed in a manner in which they are extended from both ends of the support plate 42, penetrate through the fastening slits 35b of the coupling part 35, and then are bent in a direction towards the center thereof.

Therefore, each of the elastic parts 44 according to the embodiment of the present invention may have a C shape in terms of the cross-section thereof, that is, an arc shape. However, the present invention is not limited thereto and various applications are possible. For example, the elastic parts 44 may be formed by folding both ends of the elastic member 40 penetrating through the fastening slits 35b.

In addition, distal ends of the elastic parts 44 may be bent or folded toward the lower surfaces of the fastening parts 34, but may be disposed so as to be spaced apart from the lower surfaces of the fastening parts 34 by a predetermined distance. This is to provide a space in which the elastic parts 44 may be elastically deformed.

As depicted in FIG. 6, in the elastic member 40, the elastic parts 44 may have lower ends disposed in a position lower than that of the lower surface of the body part 32. In addition, as the housing 30 is fastened to the heat radiation substrate 70, the lower ends of the elastic parts 44 are pressurized by the heat radiation substrate 70, such that they are finally located on the same plane as the lower surface of the body part 32, as depicted in FIG. 7.

A detailed description thereof will be provided in a description of a manufacturing method to be provided below.

The heat radiation substrate 70 is fastened to a lower portion of the housing 30 to radiate heat generated from the electronic elements 11. Specifically, the module substrate 10 to which the electronic element 11 is fastened may be seated on an upper surface of the heat radiation substrate 70 and the housing 30 may be fastened to the heat radiation substrate 70 while accommodating the module substrate 10 on the upper surface of the heat radiation substrate 70.

This heat radiation substrate 70 may be a heat sink formed of a material capable of effectively radiating heat outwardly. Meanwhile, the material of the heat radiation substrate 70 may be aluminum (Al) capable of being easily used at a relatively low cost and has significantly excellent heat transfer characteristics, or an alloy thereof. However, the material of the heat radiation substrate 70 according to the embodiment of the present invention is not limited thereto, and although it is not a metal such as graphite, or the like, various materials may be used as long as they have significantly excellent heat transfer characteristics.

In addition, the heat radiation substrate 70 may have a plurality of protrusions or slits formed on an external surface thereof in order to expand an outer area.

Meanwhile, although not depicted, the power module 100 according to the embodiment of the present invention may include the housing 30 having a molding part formed therein. The molding part may seal the module substrate 10 and the electronic elements 11 in such a manner to fill an inner space of the housing 30 therewith to be described below.

That is, the molding part is formed to cover and seal the electronic elements 11, and the inner leads of the external connection terminals 60 bonded to the module substrate 10, such that it may protect the electronic elements 11 from external environments.

In addition, the molding part may securely protect the electronic elements 11 from external impacts by enclosing the electronic elements 11 at the outer portions thereof and fixing the electronic elements 11 thereto.

The molding part may be formed of an insulating material such as a resin, or the like. Particularly, the material such as a silicone gel, a thermal conductive epoxy, a polyimide, or the like having high thermal conductivity may be used.

Next, a method for manufacturing a power module according to another embodiment present embodiment will be described.

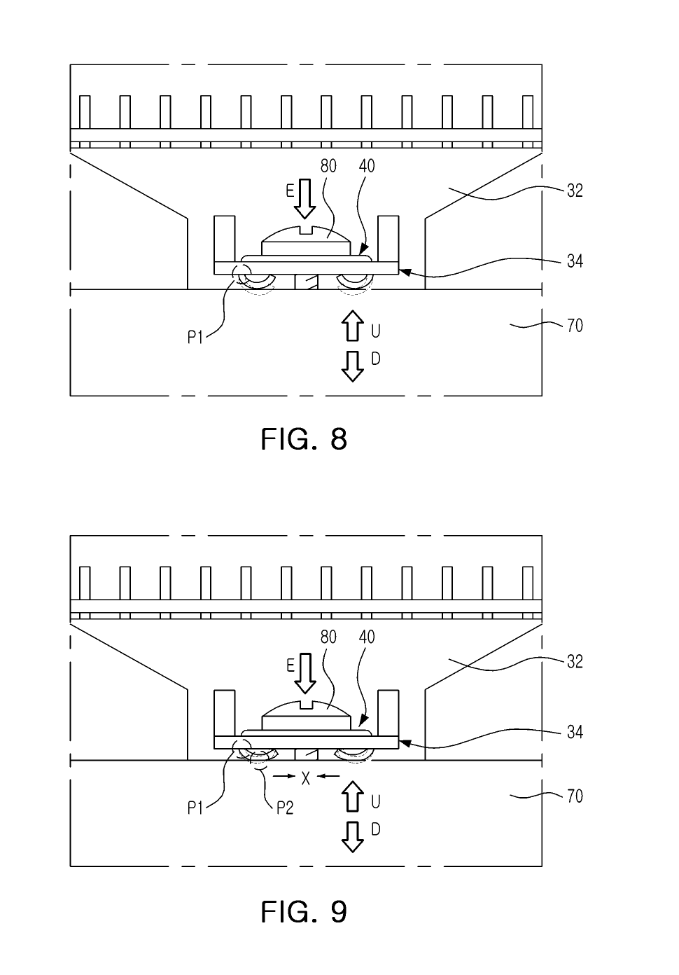

FIG. 7 is a side view taken in direction B of FIG. 1 and FIGS. 8 and 9 are partially enlarged views of part C of FIG. 7. Here, FIGS. 7 and 8 are depicted a state in which the power module is mounted on the external substrate. In addition, FIG. 8 illustrates a process in which the fixing screw is fastened, and FIG. 9 illustrates a state in which the fixing screw is completely fastened.

A method of manufacturing the power module 100 according to another embodiment of the present invention will be described with reference to FIGS. 7 through 9. First, the housing 30 to which the elastic member 40 is coupled, the module substrate 10 on which the electronic elements 11 are mounted, and the heat radiation substrate 70 are prepared.

In this case, as shown in FIG. 6, the elastic member 40 maintains an original form thereof. Therefore, the lower ends of the elastic parts 44 are located in a position lower than that of the lower surface of the body part 32 in the vertical direction.

Thereafter, as shown in FIG. 7, the housing 30 and the heat radiation substrate 70 are fastened to each other so that the module substrate 10 is accommodated in the housing 30.

Here, in the housing 30 according to the embodiment of the present invention, since the lower ends of the elastic parts 44 are located in a position lower than that of the lower surface of the body part 32, the lower ends of the elastic parts 44 contact the heat radiation substrate 70 earlier than the body part 32 of the housing 30 when seating the housing 30 on the heat radiation substrate 70.

In addition, when the housing 30 and the heat radiation substrate 70 are coupled to each other using the fixing screw 80, an interval between the upper surface of the heat radiation substrate 70 and the coupling part 35 of the housing 30 is gradually narrowed by force (E of FIG. 8) applied by the fixing screw 80. The fastening parts 34 may pressurize the elastic parts 44 downwardly through force E generated by the fixing screw 80.

Therefore, as shown in FIG. 8, the elastic part 44 is elastically deformed in a manner in which distal ends of a C shaped portion thereof is bent in a U direction, such that both ends of the elastic member 40 contact the lower surface of the fastening parts 34. A portion indicated by a dot line in FIG. 8 shows a state of the elastic part 44 before deformation.

In this process, since the elastic part 44 is deformed only in the U direction, the elastic part 44 may have a first inflection point P1 formed at an end portion of the C shaped portion, and deformation (primary deformation) occurs only at the first inflection point P1.

In this case, the elastic part 44 is deformed in a manner in which a curvature thereof is increased. That is, the elastic part 44 is deformed in a manner in which it is bent further at the first inflection point P1 in the U direction, such that elastic force is generated in a D direction.

Meanwhile, since this process generates elastic deformation only at the first inflection point P1, corresponding to the force E applied by the fixing screw 80, the applied force E and the elastic force D generated therefrom may have a linear relationship.

When the fixing screw 80 is more screwed in the state in which both ends of the elastic member 40 contact the lowesr surface of the fastening parts 34, the interval between the fastening parts 34 and the heat radiation substrate 70 may be narrowed. Therefore, the elastic part 44 of the elastic member 40 is deformed (secondarily deformed) at a second inflection point P2 formed at the center portion of the C shaped portion thereof as well as at the first inflection point P1. In this case, the elastic part 44 is deformed at the second inflection point P2 in a manner in which the curvature thereof is decreased, that is, the bent portion may be straightened along the lower surface of the coupling part 35 in an X direction.

As mentioned above, in this process, the elastic part 44 is simultaneously deformed in the U direction and the X direction.

Since the elastic deformation is simultaneously generated at the first inflection point P1 and the second inflection point P2 corresponding to the force E applied by the fixing screw 80, the applied force E and the elastic force D generated therefrom may have a non-linear relationship.

As such, when the secondary deformation is generated, the elastic parts 44 provide elastic force greater than the case in which only the primary deformation is generated in the D direction. That is, as the deformation of the fastening part 34 becomes larger due to the screwing of the fixing screw 80, the elastic parts 44 provide the larger elastic force and support the fastening parts 34. Therefore, the elastic member 40 may serve to limit a range in which the fastening parts 34 are bent.

In addition, since the elastic member 40 according to the embodiment of the prevent invention prevents the interval between the fastening parts 34 and the heat radiation substrate 70 from being excessively narrower outside of a threshold value (for example, a limit at which the fastening parts are damaged) by interposing the elastic parts 44 between the fastening parts 34 and the heat radiation substrate 70, it may prevent a connection portion between the fastening parts 34 and the body part 32 being damaged by the excessive deformation of the fastening parts 34.

As set forth above, the housing for the power module according to the embodiment of the present invention may have the fastening parts protruded from the body part and disposed in a position higher than that of the lower surface of the body part. In addition, the fastening parts and the heat radiation substrate are screwed by the screw and the fastening parts are pressurized, while the housing and the heat radiation substrate are coupled to each other.

As a result, the fastening parts are elastically connected to the heat radiation substrate, and the housing and the heat radiation substrate may be firmly coupled to each other by the elasticity.

In addition, the housing for the power module according to the embodiment of the present invention has the elastic member interposed between the fastening parts and the heat radiation substrate, elastically deformed depending on the interval between the fastening parts and the heat radiation substrate, and supporting the fastening parts. Therefore, excessive bending and deformation of the fastening parts may be prevented.

Further, basically, the elastic member of the housing for the power module according to the embodiment of the present invention may be linearly and elastically deformed between the fastening parts and the heat radiation substrate but may be non-linearly deformed when the distance between the fastening parts and the heat radiation substrate is narrowed.

That is, depending on force applied to the fastening parts, as the force becomes greater, the elastic member is non-linearly and elastically deformed, thereby supporting the fastening parts by greater elastic force. Therefore, even in the case that excessive force is applied to the fastening parts, damage to the fastening parts due to the excessive force may be prevented.

The power module according to the embodiments of the present invention as described above is not limited to the above-mentioned embodiments, but may be variously applied. For example, although the case in which the housing of the power module is entirely formed to have a rectangular parallelepiped shape has been described by way of example in the above-mentioned embodiments of the present invention, the present invention is not limited thereto. That is, the housing of the power module may have various shapes such as a cylindrical shape, a polygonal shape, or the like, as needed.

Further, although the above-mentioned embodiments describe the power module by way of example, the present invention is not limited thereto and may be applied to various devices as long as they are electronic devices in which one or more power elements are packaged.

While the present invention has been shown and described in connection with the embodiments, it will be apparent to those skilled in the art that modifications and variations can be made without departing from the spirit and scope of the invention as defined by the appended claims.

What is claimed is:

1. A housing for a power module, comprising:
a body part having a space formed therein, the space accommodating a module substrate on which electronic elements are mounted;
a plurality fastening parts formed to be protruded from side surfaces of the body part; and
an elastic member coupled to the fastening parts in a plate spring manner and elastically supporting lower portions of the fastening parts.

2. The housing for the power module of claim 1, wherein the elastic member includes:
a support plate disposed on upper surfaces of the fastening parts; and
elastic parts respectively extended from both ends of the support plate to be disposed below the fastening parts, elastically deformed when the body part is fastened to a heat radiation substrate, and supporting the fastening parts.

3. The housing for the power module of claim 2, wherein the elastic parts are respectively formed to have an arc shape and are disposed such that distal ends thereof are spaced apart from lower surfaces of the fastening parts.

4. The housing for the power module of claim 2, wherein the elastic parts have lower ends thereof disposed in a position lower than that of a lower surface of the body part.

5. The housing for the power module of claim 1, wherein the fastening parts are protruded such that lower surfaces thereof are disposed on a plane different from that of a lower surface of the body part.

6. The housing for the power module of claim 1, wherein each of the fastening parts includes:
a coupling part formed to have a flat plate shape and having a fixing screw coupled thereto; and
supporting parts vertically extended from opposing side surfaces of the coupling part to supplement rigidity of the coupling part.

7. The housing for the power module of claim 6, wherein the coupling part has a lower surface thereof disposed in a position higher than that of a lower surface of the body part in a vertical direction.

8. The housing for the power module of claim 1, wherein the body part includes one or more through-holes through which external connection terminals mounted on the module substrate are externally exposed.

9. A housing for a power module, comprising:
a plurality of fastening parts protruded from side surfaces of a body part; and
an elastic member non-linearly and elastically deformed and elastically supporting lower portions of the fastening parts.

10. A power module, comprising:
a heat radiation substrate;
a module substrate disposed on the heat radiation substrate and having one electronic elements mounted thereon; and
a housing accommodating the module substrate and coupled to the heat radiation substrate,
wherein the housing includes:
a plurality of fastening parts protruded from side surfaces of the housing and coupled to the heat radiation substrate by a fixing screw, and
an elastic member coupled to the fastening parts in a plate spring manner and elastically supporting lower portions of the fastening parts.

11. The power module of claim 10, wherein the elastic member includes:
a support plate disposed on upper surfaces of the fastening parts; and
elastic parts respectively extended from both ends of the support plate to be disposed below the fastening parts, elastically deformed when the body part is fastened to the heat radiation substrate, and supporting the fastening parts.

12. The power module of claim 10, wherein the fastening parts are protruded such that lower surfaces thereof are disposed on a plane different from that of a lower surface of the body part, and
the elastic parts of the elastic member are interposed between the fastening parts and the heat radiation substrate to provide elastic force.

13. The power module of claim 10, wherein the elastic parts have a first inflection point primarily deformed and a second inflection point additionally deformed according a degree of pressurization.

14. The power module of claim 13, wherein the elastic parts are respectively formed to have an arc shape, the first inflection point is deformed in such a manner that a curvature of the elastic parts is increased, and the second inflection point is deformed in such a manner that the curvature of the elastic parts is decreased.

15. The power module of claim 10, wherein the elastic parts are non-linearly and elastically deformed and elastically support the lower portions of the fastening parts.

16. A power module, comprising:
a heat radiation substrate;
a module substrate disposed on the heat radiation substrate and having one or more electronic elements mounted thereon; and
a housing accommodating the module substrate and coupled to the heat radiation substrate,
wherein the housing includes:
a plurality of fastening parts protruded from side surfaces of the housing and coupled to the heat radiation substrate by a fixing screw, and
an elastic member non-linearly and elastically deformed and supporting lower portions of the fastening parts.

17. The power module of claim 16, wherein the elastic parts have a first inflection point primarily deformed and a second inflection point additionally deformed according a degree of pressurization.

18. The power module of claim 17, wherein the elastic parts are respectively formed to have an arc shape, the first inflection point is deformed in such a manner that a curvature of the elastic parts is increased, and the second inflection point is deformed in such a manner that the curvature of the elastic parts is decreased.
